(19) United States
(12) Patent Application Publication
(10) Pub. No.: US 2006/0256725 A1
(43) Pub. Date: Nov. 16, 2006

(54) Mobile testing system and method providing a data relay between a testing application and internal diagnostics

(76) Inventor: Glenn R. Engel, Snohomish, WA (US)

Correspondence Address: AGILENT TECHNOLOGIES INC., INTELLECTUAL PROPERTY ADMINISTRATION, M/S DU404, P.O. BOX 7599, LOVELAND, CO, 80537-0599, US

(21) Appl. No.: 11/127,509

(22) Filed: May 12, 2005

(51) Int. Cl. G01R 31/08

(52) U.S. Cl. 370/241

(57) ABSTRACT

A device is described which provides an external data link which can be connected to a mobile device to allow subsystems within the mobile device that otherwise would be unable to communicate to exchange data with each other. The device can be used in a mobile testing system for testing cellular and wireless networks and infrastructure using mobile devices. For example, the mobile devices may include both a programming environment capable of running a test application and internal diagnostics. A data relay mechanism is connected to the mobile device over a data interface, such that the test application running on the programming environment can send a receive data from the internal diagnostics of the mobile device over the data interface by using the data relay mechanism.

### TECHNICAL FIELD

The concepts described herein relate to testing and diagnostic environments for cellular and wireless networks employing mobile devices such as cellular telephones which include a data relay between a testing program running on the mobile device and the mobile device's internal diagnostics.

### BACKGROUND OF THE INVENTION

Testing systems for testing mobile devices and cellular and wireless networks and infrastructure, such as cell phone testing, or cellular or wireless network testing often uses external data ports of the mobile devices to get diagnostic information from the phone such as signal strength, the identity of the cell tower the device is communication with, the transmission power level, and other detailed diagnostic, performance, and operational parametric data for the device and/or network. In prior testing systems, the mobile device is slave to a laptop computer and other equipment which is installed in a van and driven around the area under test to characterize that part of the network. Cellular carriers and other operators of wireless networks commission this type of service according to their needs and the nature of the information they desire, such as a characterization of the carrier's coverage area.

Many existing mobile devices include the ability to run applications that can be loaded or downloaded into the devices. Consumer's use this ability to play games on the mobile devices as well as run contact, mail, and other productivity applications. Testing engineers can also use this ability to load and run testing applications directly on the mobile device. One limitation with running these testing applications on the mobile devices is that the application environment has only limited or no access to the internal diagnostics of the mobile device. The internal diagnostics of the mobile device can generate or retrieve information that would be very useful to the testing application running on the mobile device. To overcome this limitation, the mobile device is connected to a computer or other mobile device which is able to retrieve information from the internal diagnostics of the mobile device and use the information from the testing application and internal diagnostics to characterize the network or mobile device.

This required connection to a computer or second mobile device ties the mobile device being tested to bulky equipment with limited mobility, requiring that the testing equipment be housed in a van or truck to move the mobile device around the test environment.

### BRIEF SUMMARY OF THE INVENTION

The concepts set forth herein describe an external data link which can be connected to a mobile device to allow subsystems within the mobile device that otherwise would be unable to communicate to exchange data with each other. In one embodiment, the mobile device runs a test application which requires data from the internal diagnostics of the mobile device. The testing system and method further include a data relay connectable to the mobile device over a data interface. The data relay is operable to pass data between the test application and the internal diagnostics of the mobile device over the data interface.

The foregoing has outlined rather broadly the features and technical advantages of the present invention in order that the detailed description of the invention that follows may be better understood. Additional features and advantages of the invention will be described hereinafter which form the subject of the claims of the invention. It should be appreciated by those skilled in the art that the conception and specific embodiment disclosed may be readily utilized as a basis for modifying or designing other structures for carrying out the same purposes of the present invention. It should also be realized by those skilled in the art that such equivalent constructions do not depart from the spirit and scope of the invention as set forth in the appended claims. The novel features which are believed to be characteristic of the invention, both as to its organization and method of operation, together with further objects and advantages will be better understood from the following description when considered in connection with the accompanying figures. It is to be expressly understood, however, that each of the figures is provided for the purpose of illustration and description only and is not intended as a definition of the limits of the present invention.

### BRIEF DESCRIPTION OF THE DRAWINGS

For a more complete understanding of the present invention, reference is now made to the following descriptions taken in conjunction with the accompanying drawing, in which:

FIG. 1 is a block diagram of an embodiment of a mobile testing system utilizing mobile devices including a data relay; and

FIG. 2 is a flow chart of an embodiment of a mobile testing system;

### DETAILED DESCRIPTION OF THE INVENTION

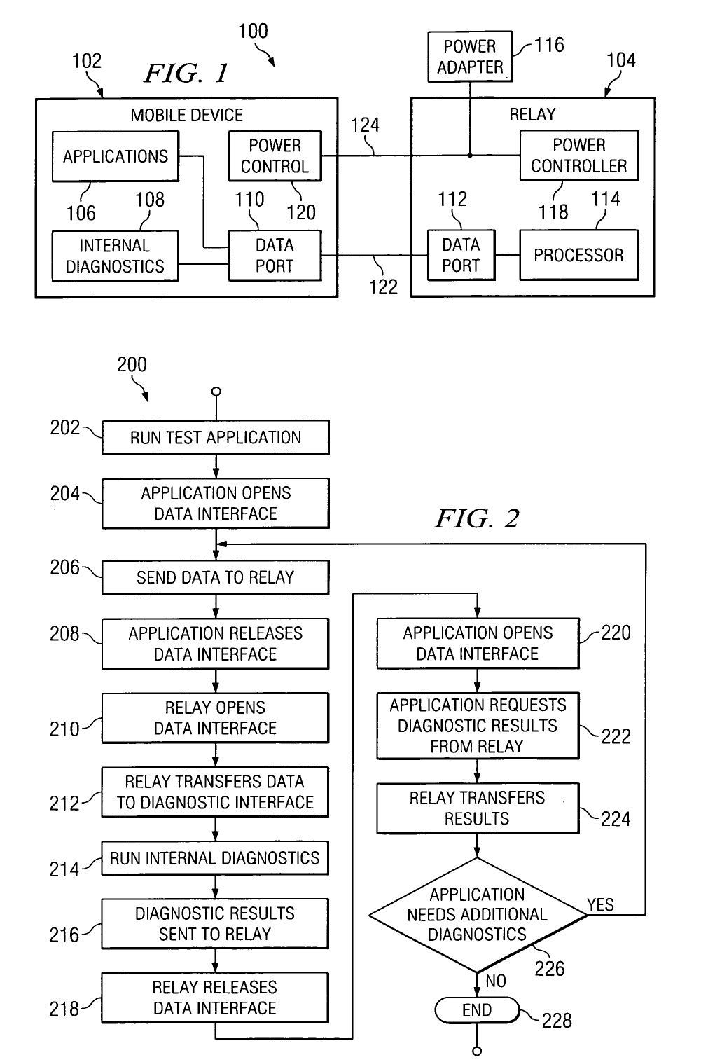

Referring now to FIG. 1, an embodiment of a mobile testing system in accordance with the concepts described herein is shown. Testing system 100 includes mobile device under test 102 and data relay 104. Mobile device 102 can be any type of mobile device including cellular phones, personal digital assistants (PDAs), pagers, combination devices, or any other similar device. Mobile device 102, in addition to its functionality as a mobile device, includes internal diagnostics 108 which can provide information such as signal strength, which cell tower it's in communication with, transmission power level, and other information pertinent to it's operating parameters, performance, conditions and environment. Mobile device 102 also provides a programming environment 106 which allows applications, including games, address books, location services and other applications to be loaded onto and run by the phone. Programming environment 106 can be Java 2 Micro Edition (J2ME) environment or any other similar environment that allows the mobile device to load and run applications.

Programming environment 106 of mobile device 102 is able to access data port 110 of mobile device 102. Data port 110 is an interface that allows mobile device 102 to be connected to and communicate with external devices. Data port 110 can be a serial interface or can be any other type of data port such as a Universal Serial Bus (USB), an infra-red data interface, a Bluetooth interface, or data port according to Recommended Standard 232, commonly known as an RS232 interface. Programming environment 106 can utilize data port 110 to communicate to devices external to mobile device 102.

Programming environment 106 can be used to run testing applications on mobile device 102. Testing applications are used to test both the mobile device and the environment of the mobile device such as the interaction between the mobile device and a wireless or cellular network environment the mobile device is operating in. Some of the information that would be useful to the testing applications running on mobile device 102 can be provided by internal diagnostics 108. Generally, however, programming environment 106 running the testing applications has no, or only very limited, access to internal diagnostics 108. To overcome this limitation, mobile device 102 is connected to data relay 104.

Data relay 104 is a small form factor device that can be connected to the mobile device without compromising the mobility of the mobile device. Data relay 104 is operable to communicate with mobile device 102 through data port 110 over data link 122. Data relay 104 includes processor 114, or some form of gate array, which is capable of receiving information from and sending information to mobile device 102 over data link 122 using data port 112 of data relay 104. Processor 114 is preferably a small programmable processor that can be programmed in accordance with the concepts described herein, but can be any programmable processor or controller. One example of such a processor is the PIC microprocessor made by Microchip Technologies, Inc. of Chandler, Ariz.

Data relay 104 is capable of communication with testing applications running on programming environment 106 over data port 110. Data relay 104 is also capable of communicating with internal diagnostics 108 also over data port 110. Data relay 104 allows the testing applications to send and receive data from internal diagnostics 108 without the need for an external computer or second mobile device. One embodiment of the operation of data relay 104 will be discussed in greater detail with reference to FIG. 2.

Data relay 104 can draw the power required for its operation in one of two ways. First, data relay 104 using power controller 118 can draw power from the power source of mobile device 102 over power link 124 which is connected to power controller 120 in mobile device 102. The power source of mobile device 102 is usually a battery or battery pack, but can be any suitable power source. Second, data relay 104 can operate as a pass through for a power adapter 116 providing power to mobile device 102. In the second arrangement, power adapter 116 is connected to data relay 104 and data relay 104 is connected over power link 124 to mobile device 102 where both data relay 104 and mobile device 102 draw power from power adapter 116. Power adapter 116 can be any suitable external power source, such as an AC adapter. While power link 124 and data link 122 are shown as separate connections in FIG. 1, the links can be separate physical connections or can both be part of the same physical interconnection between mobile device 102 and data relay 104.

Referring now to FIG. 2, a flow chart is shown illustrating an embodiment of a testing method for mobile devices in accordance with the concepts presented herein. To illustrate the operation of test method 200 reference will be made to the elements forming test system 100 from FIG. 1. Testing method 200 begins with process 202 which shows the running of a test application, such as the running of a test application in programming environment 106 in mobile device 102. The test application requires information which resides in or can be generated by internal diagnostics 108. As programming environment 106 has no interface (or very little) with internal diagnostics 108, the test application must use data relay 104 to get the data from internal diagnostics 108. Therefore, process 204 of method 200 shows the test application opening a data interface, such as data link 122, between mobile device 102 and data relay 104.

The method then proceeds to process 206 which shows the test application sending data to data relay 104 over the data interface opened in process 204. The data sent between the data relay and mobile device can be any type of information, commands, data, parameters, instructions or any other type of data that would be useful, all of which is envisioned by the term data as used herein. After the data has been sent, the method proceeds to process 208 where the test application releases the data interface. In process 210 the data relay opens the data interface between the data relay and the internal diagnostics of the mobile device. Next, in process 212 the data relay transfers the data, or a subset of the data, to the internal diagnostics of the mobile device. Process 214 then shows the internal diagnostics running or retrieving the data required by the test application in accordance with the data passed through the data relay.

After the internal diagnostics have generated or retrieved the data requested by the test application, the data is sent to the data relay as represented by process 216. After the data relay has the data from the internal diagnostics, the data relay releases the data interface, shown by process 218, and waits for the test application. In process 220 the test application opens the data interface with the data relay, and then, in process 222, requests the data, or a subset of the data, sent from the internal diagnostics to the data relay. Process 224 shows the data relay transferring the data to the test application. Process 226 represents a determination of whether the test application needs additional data from the internal diagnostics. If the determination is made that there is additional data required the process returns to process 206 where method 200 is resumed as described above. If the determination in process 226 is made that the application does not need additional information at this time, the method proceeds to process 228 which represents the end of method 200.

In the embodiment described with respect to method 200, the data relay is operable to establish connections and to pass data between the programming environment of the mobile device and the internal diagnostics of the mobile device. The embodiment described in method 200 contemplates the data relay being an essentially passive device with respect the data that is relayed. In other embodiments, however, the data relay may perform some manipulation of the data as it passes through the data relay. In yet another embodiment, instead of being a physical device the data relay could be implemented as a software module on the mobile device.

Although the present invention and its advantages have been described in detail, it should be understood that various changes, substitutions and alterations can be made herein without departing from the spirit and scope of the invention as defined by the appended claims. Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A device for providing a data link between subsystems of a mobile device, the device comprising:
a data relay connectable to the mobile device using a data interface of the mobile device, the data relay operable to use the data interface to transfer data between the subsystems of the mobile device

2. The device of claim 1 wherein the subsystems of the mobile device are a programming environment and internal diagnostics

3. The device of claim 2 wherein the programming environment is operable to run a test application which uses information from the internal diagnostics.

4. The device of claim 1 wherein the data interface is chosen from the group consisting of: a serial interface; an RS232 interface; a Universal Serial Bus interface; a Bluetooth interface; and an infra-red interface.

5. A mobile testing system including a mobile device, the mobile device running a test application and having internal diagnostics, the testing system comprising:
a data interface;
a data relay connectable to the mobile device using the data interface, the data relay including a processor operable to pass data between the test application and the internal diagnostics over the data interface.

6. The system of claim 5 further comprising a power adapter connected to the data relay, the power adapter supplying power to the data relay and further supplying power to the mobile device over a power link between the data relay and the mobile device.

7. The system of claim 5 wherein the test application runs on a programming environment in the mobile device.

8. The system of claim 7 wherein the programming environment is a Java 2 Micro Edition environment.

9. The system of claim 5 wherein data interface includes a data port on the data relay and a data port on the mobile device.

10. The system of claim 5 wherein the data interface is chosen from the group consisting of: a serial interface; an RS232 interface; a Universal Serial Bus interface; a Bluetooth interface; and an infra-red interface.

11. The system of claim 5 wherein the data relay draws power from the mobile device.

12. The system of claim 5 wherein the data interface can communicate with only one of the test application and the internal diagnostics at a time.

13. A method of testing including a mobile device, the mobile device having a test application and internal diagnostics, the test application and internal diagnostics using a data relay to pass data there between, the method comprising:
running a test application wherein the test application requires data from the internal diagnostics;
transferring data from the test application to the data relay;
transferring the data from the data relay to the internal diagnostics;
transferring return data from the internal diagnostics to the data relay; and
transferring the return data to the test application.

14. The method of claim 13 further comprising a data interface between the mobile device and the data relay.

15. The method of claim 14 further comprising, before transferring, opening the data interface.

16. The method of claim 15 further comprising, after transmitting, closing the data interface.

17. The method of claim 13 further comprising determining if the test application requires additional data from the internal diagnostics, and repeating the method beginning with transferring the data from the test application to the data relay when it is determined that the test application requires additional data.

18. The method of claim 13 wherein the data interface is chosen from the group consisting of: a serial interface; an RS232 interface; a Universal Serial Bus interface; a Bluetooth interface; and an infra-red interface.

19. The method of claim 13 further comprising, before transferring the return data to the test application, waiting for a request from the test application to the data relay for the return data.

20. A testing system comprising:
a mobile device, the mobile device running a test application and having internal diagnostics;
an interface means allowing data transfer to and from the mobile device; and
data relay means connecting to the mobile device using the interface means, the data relay means for passing data between the test application and the internal diagnostics over the interface means.

21. The testing system of claim 20 further comprising power means for powering the testing system.

22. The testing system of claim 21 further comprising a power link between the mobile device and the data relay means, and wherein the power means connects to the data relay means and the powers means supplies power to the mobile device over the power link.
